(19) United States
(12) Patent Application Publication
(10) Pub. No.: US 2023/0056012 A1
(43) Pub. Date: Feb. 23, 2023

(54) Diamond Structures For Tooling

(71) Applicant: AKHAN Semiconductor, Inc., Gurnee, IL (US)

(72) Inventors: Adam Khan, San Francisco, CA (US); Kiran Kumar Kovi, Buffalo Grove, IL (US)

(21) Appl. No.: 17/975,027

(22) Filed: Oct. 27, 2022

Related U.S. Application Data
(63) Continuation-in-part of application No. 17/869,491, filed on Jul. 20, 2022.
(60) Provisional application No. 63/223,752, filed on Jul. 20, 2021.

(51) Int. Cl. C23C 16/27; H01L 21/683; C30B 25/18; C30B 29/04

(52) U.S. Cl. CPC C23C 16/27; H01L 21/6838; C30B 25/18; C30B 29/04

(57) ABSTRACT

A substrate for a tool including at least one sidewall includes at least one diamond layer. The diamond layer has a thickness between 10 nanometers and 1000 nanometers and is formed from diamond grains sized to be 50% or less of diamond layer thickness, with the diamond coating being deposited on the surface of the substrate over the at least one sidewall.

### RELATED APPLICATIONS

This application is a continuation-in-part of U.S. patent application Ser. No. 17/869,491, filed Jul. 20, 2022, which claims the benefit of U.S. Provisional Application No. 63/223,752, filed Jul. 20, 2021, both of which are fully incorporated herein by reference.

### TECHNICAL FIELD

The present disclosure relates generally to the field of diamond and other materials and coatings for improving tooling properties. More specifically, diamond bump structures and methods for manufacture are disclosed for wafer support tooling.

### BACKGROUND

There is a demand for tooling having coatings or structures that improve performance. For example, tools may have coatings that improve hardness, reduce wear, reduce chemical reactivity, or increase or decrease frictional properties.

As an example, semiconductor wafers can be handled with vacuum or electrostatic chuck tools that that can be coated with materials that reduce wear. Coated chuck tools need to support and move wafers through many steps of wafer lithography and processing with nanometer scale precision. Unfortunately, wafers can twist or droop. When lowered onto a wafer chuck, the wafer can be prevented from flattening or moving into the correct position by friction between the wafer and chuck tool. To reduce such frictional effects, contact area between the wafer and the chuck tool can reduced by providing raised regions of near uniform height, typically regularly spaced, on the chuck tool. These raised regions are known as burls and can help in reducing the friction so that the wafer can move across the burls as its flattens and settles on the chuck tool. Often, non-uniform or malformed burls can abrade or damage the wafer.

Materials, structures and procedures that reduce or eliminate issues with friction and abrasion for tooling are needed.

### BRIEF DESCRIPTION OF THE DRAWINGS

Non-limiting and non-exhaustive embodiments of the present disclosure are described with reference to the following figures, wherein like reference numerals refer to like parts throughout the various figures unless otherwise specified.

FIGS. 1A and 1B are cross-sectional and top views of a conformal diamond coated tool surface with protrusions;

FIG. 1C is a photograph of a cross section of a conformal diamond coated protrusion;

FIG. 1D illustrates selected diamond grain sizes;

FIG. 2 illustrates one embodiment of a process for manufacture of conformal diamond coated tool surface;

FIG. 3 illustrates one embodiment of a substrate including various protuberances, cavities, sidewalls, and edges; and

FIG. 4 illustrates one embodiment of a semiconductor wafer handling tool.

### DETAILED DESCRIPTION

In some embodiments such as described with respect to the disclosed Figures and specification a substrate or tool such as a wafer handler or wafer chuck can include a surface having at least one protrusion. A substrate or tool can be coated with a layer, coating, or film that can be formed from one or more diamond layers or diamond layers in combination with metal, ceramic, or other material layers. Such a diamond layer, film, or coating can be formed from diamond grains sized so that 90% of the grains are between 200 and 300 nanometers, with the diamond coating being deposited at a temperature respectively below 600, 500, or 450 degrees Celsius over the at least one protrusion. Dopants can be used to provide electrical conductivity needed for an electrostatic wafer chuck.

In some embodiments, the at least one protrusion is a burl or plurality of burls that at least partially extend over the tool surface and can support a wafer or other object.

In some embodiments, the diamond coating is formed to have equally sized grains of less than 1 micron. The diamond coating can be formed to continuously or partially cover the tool or burl protrusions.

In some embodiments the diamond coating thickness is between 200 nanometers to 100 microns. The diamond coating can be uniformly thick over selected regions of the tool or can be conformal over regions of the tool.

In one embodiment a method for diamond coating a tool includes the steps of providing a tool a surface having at least one protrusion and forming a diamond coating over the at least one protrusion. The diamond coating can be formed from diamond grains sized so that 90% of the grains are sized between 200 and 300 nanometers. The diamond coating can be deposited at a temperature below 500 degrees Celsius over the at least one protrusion.

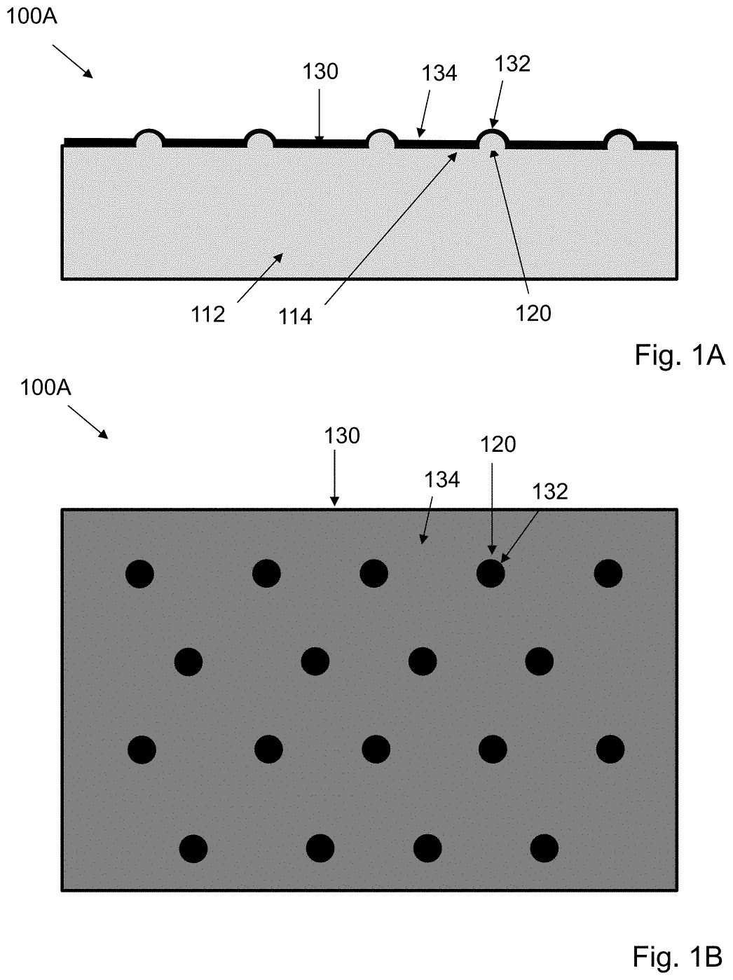

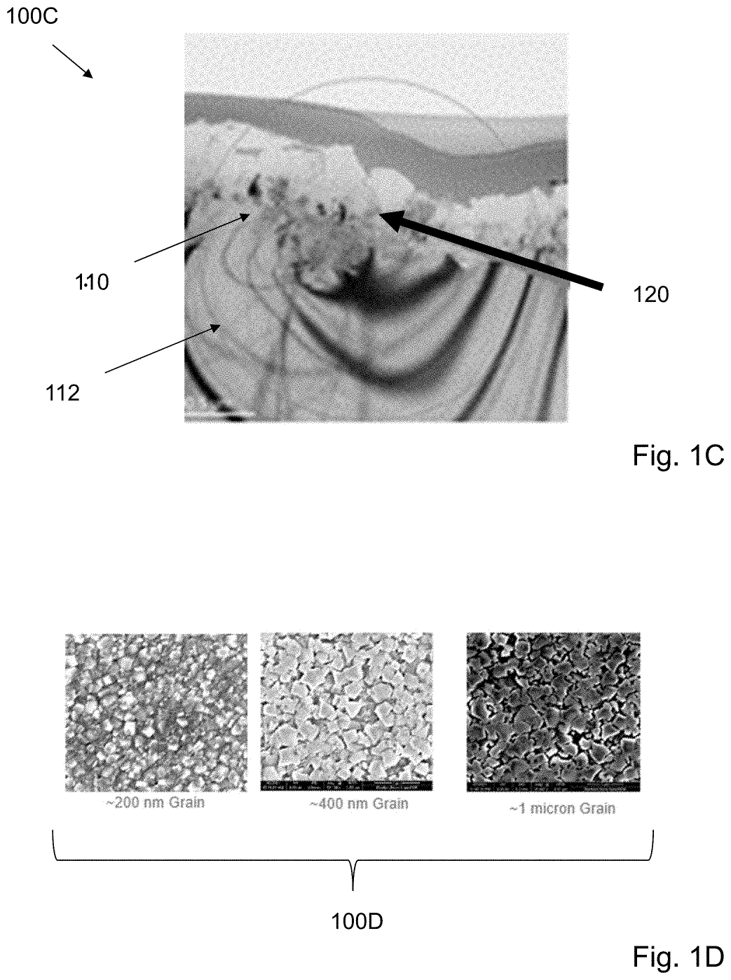

FIGS. 1A and 1B are cross-sectional (FIG. 1A) and top (FIG. 1B) views of a portion of tool 100A. The tool 100A includes a substrate 112 having a surface 114. Also present are protrusions 120 that extend away from the substrate 112. These protrusions 120 can be coated with a diamond film 130 that extends over the protrusions 120 (e.g. diamond film portion 132) and other portions of the tool surface 114 (e.g. diamond film portion 134) to provide friction reducing, protective, thermal transfer, or other needed properties. In some embodiments, the diamond film 130 conformally coats protrusions, with thickness of the coating remaining constant, or with a diamond coating thickness that varies by respectively less than 500, 300, or 100 nanometers as it extends over each of the protrusions 120. The tool 100A can be coated entirely with diamond film, coated on one or more sides, or coated in selected regions.

Tools can include but are not limited to precision carriers, graspers, lifters, or other handling tools. Tools can also include needles, pins, injectors, nano or micropipes, fluid handling channels or manifolds. Additionally, tools can be used for drilling, cutting, grinding, polishing, or insertion.

In some embodiments a tool can be a semiconductor wafer handling tool such as wafer chuck, wafer holder, wafer stage, wafer tables, wafer substrate, die scanner, wafer table for chemical mechanical polishing (CMP), or wafer transporter. For electrostatic wafer chucks or other electrically active tooling, p- or n-doping of the diamond film can be provided. In other embodiments, tools requiring or using nanoscale projections to influence mechanical, electrical, or chemical properties of the tool can be coated with diamond material. In still other embodiments, tools can be sensors or other systems that can use nanoscale projections to provide multiple point contact with other materials or the environment. For example, diamond coated sensors can be incorporated into a wafer chuck.

In some embodiments, the substrate material of the tool 100A can include Si, SiC, SiSiC, amorphous silicon, diamond-like carbon, metal-doped oxides glass materials; polymeric materials; ceramics including quartz, sapphire, and the like; metals and metal alloys; and mixtures and combinations thereof.

In some embodiments, the protrusions can include burls, mesas, bumps, pins, islands, surface structures, nano-projections, and the like. In accordance with an embodiment, protrusions on a wafer chuck may have a size, spacing, and composition that allows the maintaining of a substantially uniform pressure across the surface of wafer, and of a substantially uniform distribution of the force between the protrusions and the substrate.

In one embodiment, protrusions for wafer handling can include burls formed on a wafer tool by selective growth. Alternatively, burls can be formed by applying photoresist, patterning the photoresist, and dissolving unprotected regions. In still other embodiment, laser sintering or other additive manufacturing techniques can be used to form tool burls. Burls can be formed from substrate material, from thin films layered on the substrate, from low CTE glass-ceramic such as cordierite, from silicon carbide (SiC), from SiSiC, from aluminum nitride, or can contain SiC in the form of a composite material such as reaction-bonded SiC.

In some embodiments, there can be many hundreds or thousands of burls distributed across a wafer tools, with each wafer tool having a diameter that is typically 100 mm, 150 mm, 200 mm, 300 mm, or 450 mm. Tips of the burls typically have a small area, e.g. less than 1 square millimeter. The burls can have a width (e.g., diameter) less than or equal to 0.5 mm. In an embodiment the burls have a width (e.g., diameter) in the range of from about 200 μm to about 500 μm. The spacing between burls can be between about 1.5 mm to about 3 mm.

Burls can be arranged to form a pattern and/or may have a periodic arrangement. The burl arrangement can have a regular triangular, hexagonal, square, or radial symmetry that can vary as to provide needed distribution of force from the wafer tool to the wafer. Alternatively, burls can be laid out semi-randomly, randomly, or in partially symmetric layouts. The burls can have the same shape and dimensions throughout their height but are commonly dome shaped, cone shaped, hemispherical, pyramidal, needle-like or tapered. Typically, burls project from the wafer tool in the range of from about 1 μm to about 5 mm, and often project from about 5 μm to about 250 For best wafer handling results, the burls can be formed to have consistent dimensions. Variation between heights of different burls is minimized for best wafer handling results.

In some embodiments, burls or other protrusions coated with diamond film 120 can include coatings of various diamond, diamond-like, or diamond containing materials and structures. For the purposes of this disclosure, diamond refers to a crystalline structure of carbon atoms bonded to other carbon atoms in a lattice of tetrahedral coordination known as sp³ bonding. Each carbon atom can be surrounded by and bonded to four other carbon atoms, each located on the tip of a regular tetrahedron. In some embodiments the tetrahedral bonding configuration of carbon atoms can be irregular or distorted, otherwise deviate from the standard tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond. In one embodiment, the amount of carbon in the amorphous diamond can be at least about 90%, with at least about 20% of such carbon being bonded in distorted tetrahedral coordination. Amorphous diamond can have a higher atomic density than that of diamond. In other diamond film embodiments, diamond-like carbon can be formed as a carbonaceous material having carbon atoms as the majority element, with a substantial amount of such carbon atoms bonded in distorted tetrahedral coordination. Diamond films can include a variety of other elements as impurities or as dopants, including without limitation, hydrogen, sulfur, phosphorous, boron, nitrogen, silicon, or tungsten. This can be useful, for example, in modifying electrical or chemical diamond film properties to support tool requirements.

Diamond deposition can be by any process such as, but not limited to, chemical vapor deposition (CVD) and physical vapor deposition (PVD). A wide variety of embodiments of vapor deposition method can be used. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, cathodic arc, and the like.

In some embodiments, a thin diamond film can be deposited at relatively low temperatures of less than 600, 500, or 450 degrees Celsius using an activation medium like plasma, argon gas and a carbon source, such as methane. In other embodiments, deposition can be at temperatures between 375 and 425 degrees Celsius. Advantageously, as compared to conventional 700-800 degree Celsius temperatures for diamond film growth, such low temperatures greatly reduce thermal warping of tooling, including wafer handling tools. Warping is reduced for partially coated tools, tools that are diamond coated on one side, tools coated on both sides, or tools that are entirely coated with a diamond film.

In some embodiments, deposition gas is ignited to produce a continuous, thin, and conformal diamond layer. The type and structure of diamond deposited is dependent on the seed method used. Large grain seed can result in microcrystalline diamond with increased hardness. Small grain sizes in nanocrystalline diamond can provide lower surface roughness.

Properties of diamond film can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization for the diamond films formed as indicated in this disclosure can be between 5-10.

In some embodiments the diamond film can be conformally deposited over as a continuous layer over the surface 114 of the tool 100A. Alternatively, with the use of masking, etching, or suitable growth enhancing or growth reducing techniques, only selected area(s) can be provided with a diamond film. In some embodiments, diamond film thickness can be constant across the surface, while in other embodiments thickness can vary according to position.

In some embodiments, diamond film thickness can be constant across the surface, while in other embodiments thickness can vary according to position. Diamond coating thickness can be between 200 nm to 100 microns. In some embodiments, diamond coating thickness can be between 200 nm to 10 microns. In some embodiments, diamond coating thickness can be between 200 nm to 1 micron. In some embodiments, diamond grain size can be between 200 and 300 nanometers. In some embodiments, 90% of the diamond grains are between 200 and 300 nanometers. In other embodiments, 95% of the diamond grains are between 200 and 300 nanometers, and in still other embodiments, 99% of the diamond grains are between 200 and 300 nanometers.

FIG. 1C is a photograph of a cross section of a conformal diamond coated protrusion.

FIG. 1D illustrates selected diamond grain sizes. As illustrated, 200 nm, 400 nm, and 1 micron grain sizes are shown. As is apparent, grain sizes are nearly uniform, with at least 90% of the diamond grains being sized between 200 and 300 nanometers

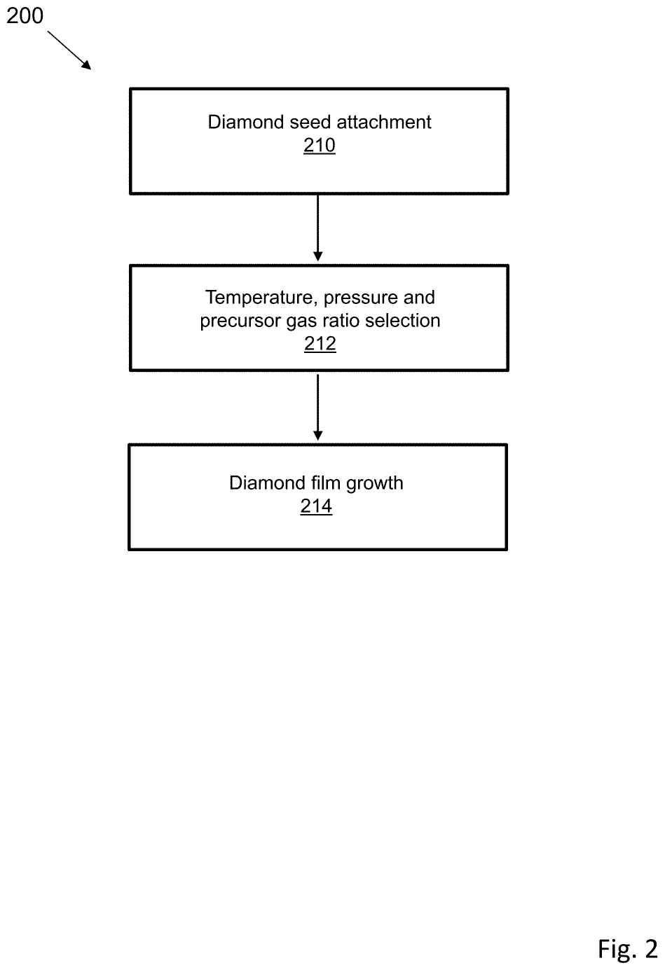

FIG. 2 illustrates one embodiment of a process 200 for manufacture of a diamond coated tool surface. In a first process step 210 diamond seeds are attached to a tool surface. Suitable diamond seeds with sizes between 5 nm to 25 um can be attached to the substrate by sonication. This increases nucleation density, improves uniformity, and speeds growth rate. Seeding techniques can varied as necessary to provide desired diamond film thickness thicknesses and grain size.

In a second process step 212 temperature, pressure and precursor gas ratios can be selected to achieve the desired film thicknesses and grain size. In some embodiments the precursor gases can include methane, hydrogen, and argon. Other minor proportions of gases such as boron, nitrogen, or phosphorus can be used if desired. Low temperature growth at pressures of 10-100 Torr can be selected.

In a third process step 214 diamond films are grown in either a hot filament CVD reactor or a microwave plasma reactor. In case of HFCVD rector, tungsten or tantalum filaments are used, and they can be carburized prior to nucleation and growth. In some embodiments, grown diamond films can have grain sizes categorized as microcrystalline (typically 500 nm or greater), nanocrystalline (typically 10-500 nm) or ultra-nanocrystalline (typically 2 to 10 nm).

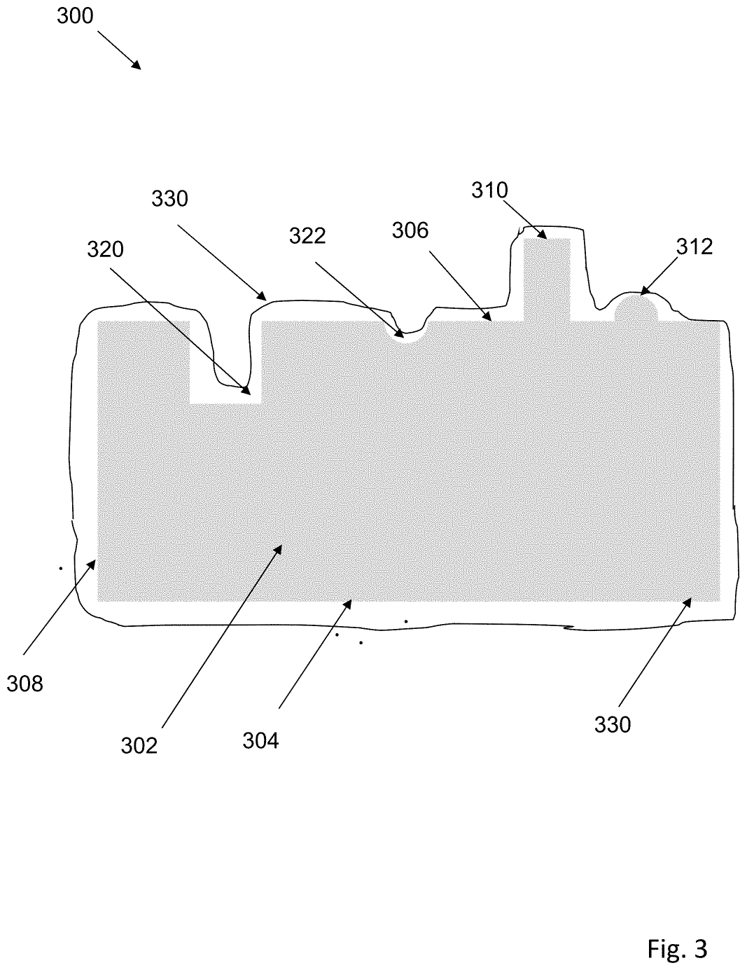

FIG. 3 illustrates one embodiment of a tool 300 in cross section, including a representative substrate 302 having a bottom surface 304, top surface 306, and sidewall or edges 308. Various protuberances 310 (shaped to be vertically edged) and 312 (shaped to be curved or hemispherical) are shown. Similarly, various cavities 320 (shaped to be vertically edged) and 322 (shaped to be curved or hemispherical) are shown. In some embodiments, a cavity can extend entirely through the substrate. In one embodiment, a conformal and continuous diamond coating 330 can be deposited to cover the bottom surface 304, top surface 306, and sidewall or edges 308.

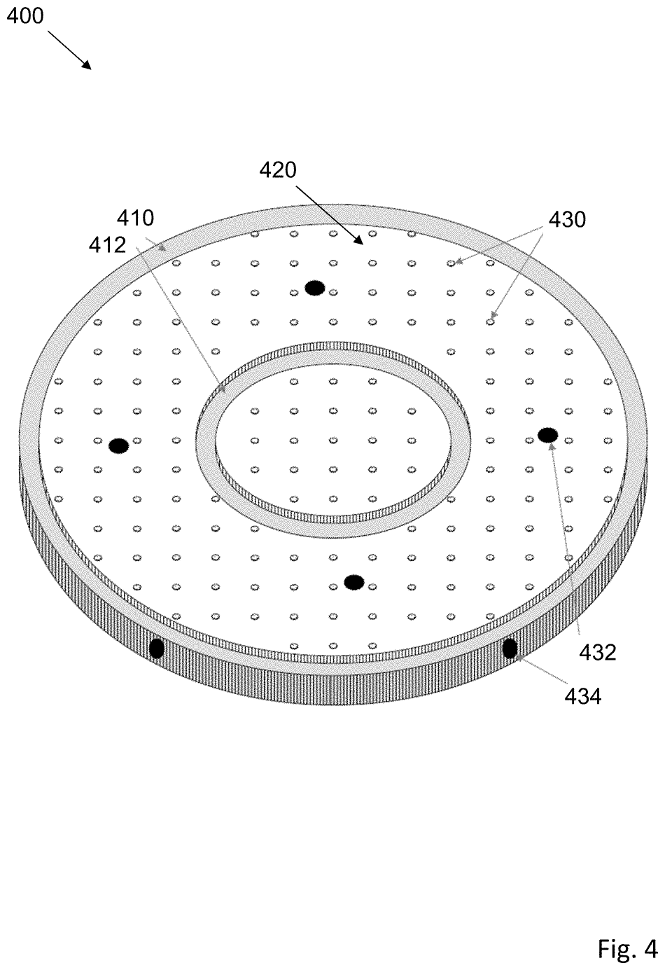

FIG. 4 illustrates one embodiment of a wafer handling tool 400 in perspective, including a sidewall 410 and inner ring 412. A surface 420 includes numerous protuberances 430 that can be coated with a diamond layer and used to support wafers. Cavities or holes 432 and 434 can be a portion of a vacuum system used to hold a wafer (not shown) against the wafer handling tool 400. Diamond layer thickness can range from 300 to 3000 nanometers, 400-800 nanometers, or 500 to 700 nanometers. In some embodiments, diamond grain size can range between 50-500 nanometers, with at least 50%, 60%, 70%, 80%, or 90% of diamond grains being within this range of grain size.

Example 1—In other embodiments, nanocrystalline diamond can be deposited on SiSiC substrates that are between 2 and 12 inches in diameter. The SiSiC components can have burls (or buds extending out) that are flat at the top and have angled sidewalls with defined slope. The thickness of these burls can be around 1 to 1.5 mm. Seeding with different sizes can be used. Seeding with 20-30 nanometer diamond grains together with 10, 15 and 25 nanometer grains can be used to obtain high nucleation density, achieving uniform diamond coating across a 12 inch Si SiC wafer.

Example 2—After the deposition of a continuous diamond layer or film, the diamond layer or film can be etched using, for example, an aluminum mask. Islands of squares and circular structures, including but not limited to those formed as SiC/SiSiC burls or other substrates, can be defined. By adopting different seed mixtures, final thickness and grain size of diamond can be selected.

Example 3—Tools having structures generally configured as pyramids or cones with the tip radius of 200 nm to 2 um can be fabricated through reactive ion etching by using Al as the mask.

In some embodiments, single or multiple diamond layers or films suitable for coating tools can be a component of a multilayer coating or film system applied to a wide variety of substrates. Such diamond layers or films can include multilayer structures that enable or enhance various usages or features, including those that provide for light redirection, interference, cover glass, protective covers, displays, windows, chemical, thermal, or mechanical protection. Applications or components supporting multilayer diamond layers, films, or coatings can include but are not limited to visible or infrared optics, windows, optical waveguides, semiconductors, semiconductor coatings, and rugged or durable coatings for electronics, manufacturing, or tooling. Other applications for diamond multilayer coatings can include use in biological substrates or medical devices, or use in batteries, fuel cells, electrochemical systems, chemo-sensors, general sensing, or integration with other advanced materials.

As used in this disclosure, the terms “layer”, “film”, and “coated” can be interchangeably used, and refer to thin deposited, chemically formed, grown materials, or otherwise situated materials on a substrate that can itself be a layer, film or coating. Diamond layers or films can include intrinsic diamond, diamond-like material, or diamond with small amounts of graphite or other materials. Diamond lattice structure can be selectively modified and can include provision of varying sp2/sp3 carbon materials positioned through selective seeding or etch, nucleation or growth process parameters including gas composition, pressure, and temperature among other parameters, selective laser annealing, particle bombardment or doping, or use of laser pulse to grow diamond. Modification of diamond layers or films by oxygen termination, hydrogen termination, chlorine or fluorine functionalization are additional embodiments.

In some embodiments, diamond layers intended for sensing, waveguide, or electronic usage can benefit from doping, including p-doping and n-doping. Dopants including but not limited to P, B, Li, or H can also be added. In some embodiments, introducing a minimal amount of acceptor dopant atoms to a diamond lattice can additionally create ion tracks. The creation of the ion tracks may include creation of a non-critical concentration of vacancies, for example, less than 10²²/cm³ for single crystal bulk volume, and a diminution of the resistive pressure capability of the diamond layer. For example, acceptor dopant atoms can be introduced using ion implantation at approximately 80 degrees Kelvin (K) to 600 K. In other embodiments, acceptor dopant atoms can be introduced using ion implantation at 293 to 298 degrees Kelvin in a low concentration. The acceptor dopant atoms may be p-type acceptor dopant atoms. The p-type dopant may be, but is not limited to, boron, hydrogen and lithium. In one embodiment, ion tracks that act as a ballistic pathway for introduction of larger substitutional dopant can be created. This allows placement of substitutional dopant atoms into the diamond lattice through the ion tracks. For example, larger substitutional dopant atoms using ion implantation placed at or below approximately 78 degrees K for energy implantation at less than 500 keV. Implanting below 78 degrees K can allow for the freezing of vacancies and interstitials in the diamond lattice, while maximizing substitutional implantation for the substitutional dopant atoms. The larger substitutional dopant atoms may be for example, but is not limited to, phosphorous, nitrogen, sulfur and oxygen. Such larger substitutional dopant atoms may be introduced at a much higher concentration than the acceptor dopant atoms. The higher concentration of the larger substitutional dopant atoms may be, but is not limited to, approximately 9.9×10¹⁷/cm³ of phosphorous and a range of 8×10¹⁷ to 2×10¹⁸/cm³. As another example, nitrogen can be implanted at a concentration of up to 9×10¹⁸/cm³.

In some embodiments, a diamond layer can have a sp2 concentration of less than 20% by diamond layer volume. In other embodiments, a diamond layer can have a grain orientation at least 80% in either the <111> or <100> crystalline direction. In still other embodiments, a highly oriented diamond film can include differing crystal orientations in selected region or layers, with <111> and <100> crystalline direction respectively predominating.

Properties of diamond in the multilayer coating or film system can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization for the diamond layers or films formed as indicated in this disclosure can be between 5-15. In other embodiments, a diamond layer can have a Raman spectrographic signature of diamond (approximately 1332 nm) at least or greater than 0.5:1 as compared to peak Graphitic Band (1400-1600 nm) by Raman Analysis. In other embodiments, a diamond layer can have physical properties such as Vickers hardness measured by nanoindentation of at least 12 Gigapascal or greater than 20 Gigapascal. In other embodiments, a diamond layer can be measured to exert a compressive stress less than 50 Gigapascal.

In some embodiments, substantially monocrystalline diamond can be formed on at least a portion of a substrate. In other embodiments, polycrystalline diamond or diamond-like material can be formed on all or at least a portion of the substrate. In some embodiments, polycrystalline diamond grains sized to be less than 1 micron (1000 nanometers) and greater than 500 nanometers can be used. In other embodiments, polycrystalline diamond or diamond-like material can include ultrananocrystalline grain sizes (2-10 nanometers), nanocrystalline grain sizes (10-500 nanometers), or microcrystalline grain sizes (500 nanometers or greater). In some embodiments, diamond grain size can include a range of grain sizes, including larger and smaller grains. In some embodiments, a diamond layer can be formed to have grains of less than 1 microns. In some embodiments, grain size can differ by greater or less than 50%, 100%, 200% or 500% of mean diamond grain size. In other embodiments, diamond grain size can be maintained to within 50%, 20%, or 10% of mean grain size. In some embodiments, 50%, 60%, 80%, or 90% of the diamond grains can be sized between 50 and 500 nanometers. In some embodiments, a diamond layer can be formed from at least 90% nanocrystalline diamond and have diamond grains sized between 2 nanometers and 500 nanometers. In some embodiments, a diamond layer can be formed from at least 90% microcrystalline diamond and have diamond grains sized between 500 nanometers and 1000 nanometers. In other embodiments, diamond grains can be sized between 500 nanometers and 1000 nanometers. In other embodiments, 90% of the diamond grains can be sized between 200 and 300 nanometers.

In some embodiments, diamond grain size in a diamond layer can be controlled to improve particular optical, thermal, or mechanical characteristics of a diamond layer containing multilayer coating or film system. For example, optical transparency can be increased by use of ultrananocrystalline or nanocrystalline sized grains that are sized between 2 nanometers and 30 nanometers.

Diamond layer thickness in some embodiments can be selected to be between 200 nanometers and 100 microns. Typically diamond grain size will be 50% or less of diamond layer thickness. In some embodiments useful for optical coatings, diamond layer thickness will be between 20 and 200 nanometer. For example, in one embodiment a glass or other transparent material can be coated with a diamond film having a thickness between 10 nanometer and 1000 nanometer thickness. When used in optically transmissive systems, the diamond film provides transmission of light through the glass substrate and the diamond film at 550 nanometer wavelength is in excess of 0.60, 0.70, 0.80 or 0.90, the transmission of light between 350 nanometer and 450 nanometer wavelength is less than 0.60, 0.70, 0.80 or 0.90, and the transmission of light between 750 nanometer and 850 nanometer of less than 0.60, 0.70, 0.80 or 0.90. In other embodiments of optically transmissive systems, the diamond film provides transmission of light through the glass substrate and the diamond film with a transmissivity in excess of 0.60, 0.70, 0.80 or 0.90 at wavelengths ranging between 500 and 600 nanometers, 530 and 570 nanometers, or 540 and 560 nanometers. In some embodiments a glass or other transparent material can be coated with a diamond film that provides haze of less 20% for thick diamond layers (e.g. ranging from 1 micron to 10 microns), less 10% for thin diamond layers (e.g. ranging from 200 nanometers to 1000 nanometers), and less 5% for very thin diamond layers (e.g. below 200 nanometers). In other embodiments, thicker diamond layer coatings of up to 10 microns can be used to improve mechanical, frictional, or thermal characteristics.

Diamond layers can have a substantially uniform thickness over all or defined portions of a surface or substrate. In other embodiments, thickness can vary over portions of a surface or substrate. In some embodiments diamond layers can be conformal when extending over cavities, depressions, or protrusions in a substrate or surface. In some embodiments, diamond layers can steadily thin or thicken away from one or more positions on a substrate. In some embodiments, thinning or thickening can be less than 20%, 10%, 6%, or 3% of diamond layer thickness over the substrate.

Multiple diamond layers distinguished by composition, crystal structure, dopants, grain size, or grain size distribution can be a part of a multilayer coating or film system applied to a substrate. Distinct diamond layers can be layered on top of diamond layers or non-diamond materials. In certain embodiments, physical parameters of diamond layers can continuously or semi-continuously change vertically or laterally through the layer.

Diamond layers can be deposited and optionally structured using selective seeding techniques. Seed layers can include use of selective deposition or etched seed areas. In some embodiments, nanocrystalline diamonds can be directly deposited or deposited in a solution.

Diamond layers, whether grown with or without seeding, can be deposited on various substrates, including but not limited to glass, ceramics, oxides, or metals. For example, a substrate can be a silicon oxide materials, SiO2, fused silica, quartz, sapphire, gallium nitride (GaN), gallium arsenide (GaAs), and refractory metals. In addition, the substrate materials may include carbon-carbon bonding allows integration with other materials such as SiC, graphene, carbon nano tubes (CNT), as well single crystal, polycrystalline diamond materials, and combinations of the materials. Substrates can be transparent, semi-transparent, or opaque at selected wavelengths or wavelength ranges. For example, in some embodiments, a substrate can have a transmissivity of 80% or greater at one of optical or infrared wavelengths. In some embodiments, a diamond layer has a transparency of greater than about 80%, for example, 81%, 82%, 83%, 84%, 85%, 86%, 87%, 88%, 89%, 90%, 91%, 92%, 93%, 94% or about 95% inclusive of all ranges and values therebetween. In particular embodiments, the diamond layer has a thickness, for example, between 30 nanometers to about 150 nanometers (e.g., about 30 nanometers, 40 nanometers, 50 nanometers, 60 nanometers, 70 nanometers, 80 nanometers, 90 nanometers, 100 nanometers, 110 nanometers, 120 nanometers, 130 nanometers, 140 nanometers, or about 150 nanometers inclusive of all ranges and values there between). Furthermore, the diamond layer can have a root mean square (RMS) roughness of less than 7 nanometers. In some embodiments, the diamond layer can have an RMS roughness of less than 50%, 40%, 30%, 20%, or 10% of the film thickness. In some embodiments, the diamond layer can have an RMS roughness of less than 20% of the diamond layer thickness.

In some embodiments, various processes can be used to improve diamond or other film quality. For example, a substrate can be subjected to dry and/or wet chemical cleaning, including but not limited to strong or weak acid and/or base cleaning, solvent cleaning, ultrasonic agitation, spray coating, plasma cleaning, ultraviolet (UV) and ozone, tetramethyl ammonium hydroxide, or any suitable combination of cleaning processes. Plasma cleaning can include subjecting a substrate to plasma derived from argon and/or oxygen in various concentrations. Ozone may be chemical ozone, derived from heated sources, or both.

In some embodiments, before deposition of a diamond or diamond like film, a substrate can be treated by sputtering, evaporation, atomic layer deposition (ALD), chemical vapor, plasma, thermal or form of deposition of one or more of materials including but limited to oxides and nitride dielectric materials, oxides of metals such as indium, tin, zinc, or combinations, oxides of graphene such as graphene oxide, reduced fluorinated graphene oxide, oxides of silicon or aluminum, nitrides of aluminum, silicon, titanium, boron, and metals such as tungsten or titanium. Advantageously in some embodiments this can reduce coefficient of thermal expansion differences, reducing interlayer and subsurface stress, and allow for tune coloration, as well as optical losses attributable to haze or reflectance.

In some embodiments, for metal deposited via sputter deposition, power levels may can be adjusted, and shutter opening times can vary to achieve the target thickness uniformly across the display glass surface. For oxides and nitrides deposited via ALD, thin films may utilize lower temperature (including temperatures less than or equal to 600° C.) and/or crystalline structure to achieve optimal integration with subsequent diamond layer.

In some embodiments, a substrate may be subjected to surface functionalization treatment steps. This can include surface functionalization by wet chemistry that includes spray coating, biased spray coating, ultrasonic spray coating, volume by ultrasonic agitation of solvent and ketone mixtures, including but not limited to methanol, acetone, isopropyl alcohol, ethanol, butanol, or pentanol. The functionalized surface can include hydrocarbon chains, hydroxyl bonds, oxygen termination, or other suitable chemically active materials.

To encourage growth of diamond films with selected grain sizes or in defined areas, a substrate can be seeded with diamond crystal particulates ranging in size from nanometer to microns. In some embodiments, seed size can range from 5 to 50 nanometers. Seeds can be functionalized, or can have a positive, negative, or neutral zeta potential. The seed crystals may be in a solvent, dimethyl sulfoxide, oil, photoresist, deionized water, a combination or similar types of suspension or matrix. Substrate coverage with diamond crystal seeds can be uniform 105-1013 grains per square centimeter, non-uniform, or localized in selected areas using masks, selective spraying, electrospraying, ultrasonic spraying, or other form of spatially localized application. In some embodiments seeds of differing sizes and characteristics can be used.

Seeded substrates can be loaded into a chemical vapor deposition (CVD) system under low vacuum pressures in the range of 30 mTorr to 300 Torr. A CVD system can be thermal, microwave, or a combination of thermal and microwave configurations. Thermal CVD can include hot filament, hot wire, optical beam, or other, while microwave can include either or both 915 MHz and 2.45 GHz systems. The substrate is then exposed to ions generated from a thermal or microwave source with originating source and reactant feed gases comprising one or more of the following: hydrogen, argon, acetylene, acetone, oxygen, methane, carbon monoxide, carbon dioxide, or other carbon containing source. In one embodiment the diamond may by be single crystal diamond. In another embodiment the diamond may be polycrystalline diamond. In one embodiment nanocrystalline sized diamond can be utilized. The deposition process may be further modified through the use of variable pressures, positive and/or negative stage biasing, stage heating and/or cooling, or control of stage to plasma source distance. The reactant and initiator gas volumes, ratios, and flow rates, temperature at the gas inlet, substrate temperature, intermediate electric field from energy source to substrate surface, and chamber pressure may be adjusted such that grown diamond films exert stress in compressive rather than tensile form. In some embodiments, this allows display glass layers to be held under compression, increasing display glass toughness and strength. Further, the thermal decomposition and ionic energy of the source gases may favor diamond properties through control of CH hydrocarbon radicals versus C₂ (dimer) hydrocarbon radical volumes.

In some embodiments, a deposited diamond film can be further cleaned, and exposed to a two dimensional top layer material, such as reduced fluorinated graphene oxide, graphene, graphene oxide, or similar materials. In some embodiments this provides for superhydrophobicity or oleophobicity without significant degradation to diamond film properties, including optical transmissivity and/or hardness. In one embodiment, graphene oxide may come from a chemical suspension of multilayer graphene oxide and spun on to the diamond film, and either wet chemically or dry chemically (plasma) reduced through inclusion of fluorine atoms into the material, in substitution to oxygen.

In some embodiments, a diamond layer coating a substrate can be subjected to further chemical and mechanical treatment such as reactive ion etching, which may produce bulk planarized uniform diamond films of the desired thickness. In one embodiment the RIE (Reactive Ion Etching) uses CHF₃ and CF₄ at a ratio of 3:1. Further planarization and/or polishing steps may be utilized to achieve desired flatness and surface finishing.

Diamond films such as described herein can be deposited on a wide variety of substrate types and shapes. Substrates can include Si, SiC, SiSiC, amorphous silicon, diamond-like carbon, metal-doped oxides glass materials; polymeric materials; ceramics including quartz, sapphire, and the like; metals and metal alloys, or mixtures and combinations thereof. In some embodiments, substrates can include aluminosilicate glass, for example, Corning Gorilla Glass®, borosilicate glass, commercial glass, for example, BK7, fused silica, quartz, sapphire, indium tin oxide, titanium dioxides, such as, but not limited to, crystalline rutile.

In some embodiments, substrate form and composition can be altered by maskless or mask etching, additive or subtractive photoresist etching, or direct mechanical cutting, drilling, or grinding. In still other embodiment, laser sintering or other additive manufacturing techniques can be used to build up a substrate into a desired form. In some embodiments, doping, sputtering, evaporation, atomic layer deposition (ALD), chemical vapor, plasma, thermal or other form of deposition can be used to deposit various materials previously discussed with respect to preparation for processing diamond films. In some embodiments, a deposited diamond layer can act as a support for additional diamond or non-diamond films.

In some embodiments, substrates can be flat, curved, smoothly continuous, and include sidewalls, edges, beveled edges, or curved edges. A surface can be of one distinct composition or can include multiple compositions. Substrate embodiments can also include single or multiple cavities, indentations, or can be channels defined therein, as well as protrusions such as pillars and projections. In other embodiments, substrates can include burls, mesas, bumps, pins, islands, irregular or regular surface structures, nano-projections, and the like. In accordance with an embodiment, cavities or protrusions can be selected to have predetermined size, spacing, and composition, while in other embodiments size, spacing, and composition can be random or semi-random.

While substrates can be mechanically rigid and have millimeter or greater thicknesses, in some embodiments a substrate includes other thin diamond layers, or thin layers of a metals, ceramics, glasses, or other compositions. Thickness of such layers can be less than 1 mm, 1 micron, or 100 nanometers. Such layers can act as intermediate or buffer layers, and can improve optical, electrical, thermal, or mechanical properties of the multilayer structure. In some embodiments, substrates or intermediate layers can be transparent and include one or more of metals (e.g. tungsten or titanium); ceramics, or glass (e.g. aluminosilicate or borosilicate). In some embodiments, substrates or an optically transparent intermediate layer can include one or more of indium tin oxide, aluminum oxide, titanium oxides including but not limited to titanium dioxide, magnesium oxide, silicon dioxide, and hafnium oxide. In other embodiments, substrates or an optically transparent intermediate layer can include one or more of nitrides of aluminum, silicon, titanium, or boron. Layers can also include but are not limited to carbon film formed of diamond-like carbon (DLC), amorphous carbon or nano-crystal diamond (NCD), or a metal film made of molybdenum, titanium, tungsten, chromium or copper, or a ceramic film formed of SiC, TiC, CrC, WC, BN, B₄C, Si₃N₄, TiN, CrN, SiCN, or BCN. The thickness of an intermediate or buffer layer can range from 10 nanometers to 100 microns, when thickness of the diamond film ranges from 10 nanometers to 1000 nanometers.

As will be understood, the described diamond layers, substrates, and thin films of non-diamond materials can include various embodiments, characteristics, and combinations, including but not limited to the following additional examples:

Example 4—In a fourth example, a transparent diamond layer can be continuously and conformally coated over the glass substrate to act as an optically clear protective coating suitable for smart phones, tablets, or laptops. For example, a substantially uniform 70-110 nanometers thick nanocrystalline film having a grain size ranging between 20 to 70 nanometers can be deposited. In some embodiments, the grain size can be diamond grains range from 5 nanometers to 50 nanometers. The glass substrate can be chemically cleaned using acetone, followed by cleaning using UV ozone, Alternatively, float glass or similar substrates can be acid cleaned to remove tin or other metallic coatings. In some embodiments the glass surface can be functionalized to include hydrocarbon chains derived from solvent breakdown while drying.

A conventional HF CVD reactor with tungsten, tantalum, or rhenium filaments can be used. Filament diameter, spacing, and number can be adjusted to provide best results. In one embodiment, filament diameter 0.12 to 0.5 mm, spacing can be 8 to 30 mm, and between 7 to 28 filaments used. Chambers can be spherical, rectangular, or cylindrical. In one embodiment, a cylindrical sphere can be sized to have a volume between 100 to 200 liters, with diameter between 30 to 150 centimeters.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour.

Precursor gases including methane, hydrogen, oxygen, and argon can be introduced into the chamber at a pressure of 10-15 Torr. In particular, addition of less than 1% oxygen can lower required temperature to maintain an expected deposition rate, and oxygen will preferentially etch sp2 deposited areas. Methane concentration can be between 0.5 to 5 percent of total gas volume. Hydrogen concentration can be between 60 to 90 percent of total gas volume. Argon concentration can be between 10 to 40 percent of total gas volume.

To ensure consistent grain size, the substrate can be coated with diamond seeds dispersed in a dimethyl sulfoxide (DMSO) or other solvent solutions including but limited to ethanol, methanol, IPA, and acetone. In some embodiments, 5 to 50 nanometer grain sizes can be used.

In some embodiments, the diamond film is continuous and conformal over the substrate.

Further, the diamond film can have a FWHM of 5-7 and an sp2 concentration of less than 20% by volume, a grain orientation of at least 80% in the <111> crystalline direction, a Raman spectrographic signature of diamond (approximately 1332 nm) of between 0.7:1 and 1.2:1 as compared to peak Graphitic Band (1400-1600 nm) by Raman Analysis, a Vickers hardness of between 20 and 60 Gigapascal, and with transmission of light through the glass substrate and the diamond film at 550 nanometer wavelength is in excess of 0.70, a haze of less than 5%.

Example 5—In a fifth example, a substrate can be coated with a substantially uniform 100-2000 nanometers thick nanocrystalline diamond layer or film having a diamond grain size ranging between 100 to 2000 nanometers. In some embodiments, the deposited grain size can include diamond grains ranging from 5 nanometers to 50 nanometers.

The reactor can include a stage capable of supporting heating or cooling of the substrate. In some embodiments the reactor stage can be set to provide a substrate deposition temperature between 500 and 800 C. At these temperature ranges, diamond layer deposition rates can be between 10 to 200 nanometers per hour.

The substrate can be coated with diamond seeds dispersed in a DMSO or other solvent solutions including but limited to ethanol, methanol, IPA, and acetone. In some embodiments, 5 to 15,000 nanometer grain sizes can be used, with larger grains typically being reduceable in size by sonication or other processing steps. Various grain sizes or grain size ranges can be used in some embodiments, including co-deposited small and large grain sizes. In some embodiments, the seeds are deposited in a manner that ensures that the film is continuous and conformal over the substrate.

In some embodiments, the diamond film can have a Young's modulus in excess of 80 Gigapascal.

Example 6—In a sixth example, a transparent substrate can be coated with multiple layers, including diamond layers, ceramic layers, or metal layers. In some embodiments, a substantially uniform 5-50 nanometers thick nanocrystalline diamond layer having a grain size ranging between 5 to 50 nanometers can be deposited.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour.

In the foregoing description, reference is made to the accompanying drawings that form a part thereof, and in which is shown by way of illustration specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The foregoing detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, databases, or characteristics may be combined in any suitable combinations and/or sub-combinations in one or more embodiments or examples. In addition, it should be appreciated that the figures provided herewith are for explanation purposes to persons ordinarily skilled in the art and that the drawings are not necessarily drawn to scale.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A structure, comprising:
a substrate having a surface including at least one sidewall; and
a diamond layer having a thickness between 10 nanometers and 1000 nanometers and formed from diamond grains sized to be 50% or less of diamond layer thickness, with the diamond coating being deposited on the surface of the substrate over the at least one sidewall.

2. The structure of claim 1, wherein the sidewall is defined on a protrusion extending away from the substrate.

3. The structure of claim 1, wherein the sidewall is defined on a cavity extending into the substrate.

4. The structure of claim 1, wherein the diamond layer is formed to continuously cover the surface of the substrate.

5. The structure of claim 1, wherein the diamond layer is formed to partially cover the surface of the substrate.

6. The structure of claim 1, wherein the diamond layer is formed to conformally cover the surface of the substrate.

7. The structure of claim 1, wherein the diamond layer is formed to thin or thicken by less than 20% across the surface of the substrate.

8. The structure of claim 1, wherein the diamond layer thickness is uniformly thick over selected regions of the surface of the substrate.

9. The structure of claim 1, wherein the diamond layer can be at least one of multiple diamond and non-diamond layers formed to cover at least a portion of the surface of the substrate.

10. The structure of claim 1, wherein the diamond layer on the surface and the sidewall is formed to have 50% of grains sized to be between 2 nanometers and 500 nanometers in size.

11. The structure of claim 1, wherein the substrate is opaque at optical wavelengths.

12. The structure of claim 1, wherein the diamond layer is deposited at less than 600 degrees Celsius.

13. A method for depositing a layer, comprising:
providing a substrate having a surface including at least one sidewall; and
depositing a diamond layer having a thickness between 10 nanometers and 1000 nanometers and formed from diamond grains sized to be 50% or less of diamond layer thickness, with the diamond coating being deposited on the surface of the substrate over the at least one sidewall.

14. The method of claim 13, wherein the sidewall is defined on a protrusion extending away from the substrate.

15. The method of claim 13, wherein the sidewall is defined on a cavity extending into the substrate.

16. The method of claim 13, wherein the diamond layer is formed to continuously cover the surface of the substrate.

17. The method of claim 13, wherein the diamond layer is formed to partially cover the surface of the substrate.

18. The method of claim 13, wherein the diamond layer is formed to conformally cover the surface of the substrate.

19. The method of claim 13, wherein the diamond layer is formed to thin or thicken by less than 20% across the surface of the substrate.

20. The method of claim 13, wherein the diamond layer thickness is uniformly thick over selected regions of the surface of the substrate.

21. The method of claim 13, wherein the diamond layer can be at least one of multiple diamond and non-diamond layers formed to cover at least a portion of the surface of the substrate.

22. The method of claim 13, wherein the diamond layer on the surface and the sidewall is formed to have 50% of grains sized to be between 2 nanometers and 500 nanometers in size.

23. The method of claim 13, wherein the substrate is opaque at optical wavelengths.

24. The method of claim 13, wherein the diamond layer is deposited at less than 600 degrees Celsius.

25. A wafer tooling structure, comprising:
wafer tooling including a substrate having a surface including at least one sidewall; and
a diamond layer having a thickness between 10 nanometers and 1000 nanometers and formed from diamond grains sized to be 50% or less of diamond layer thickness, with the diamond coating being deposited on the surface of the substrate over the at least one sidewall.

26. The structure of claim 25, wherein the sidewall is defined on a protrusion extending away from the substrate.

27. The structure of claim 25, wherein the sidewall is defined on a cavity extending into the substrate.

28. The structure of claim 25, wherein the diamond layer is formed to continuously cover the surface of the substrate.

29. The structure of claim 25, wherein the diamond layer is formed to partially cover the surface of the substrate.

30. The structure of claim 25, wherein the diamond layer is formed to conformally cover the surface of the substrate.

31. The structure of claim 25, wherein the diamond layer is formed to thin or thicken by less than 20% across the surface of the substrate.

32. The structure of claim 25, wherein the diamond layer thickness is uniformly thick over selected regions of the surface of the substrate.

33. The structure of claim 25, wherein the diamond layer can be at least one of multiple diamond and non-diamond layers formed to cover at least a portion of the surface of the substrate.

34. The structure of claim 25, wherein the diamond layer on the surface and the sidewall is formed to have 50% of grains sized to be between 2 nanometers and 500 nanometers in size.

35. The structure of claim 25, wherein the substrate is opaque at optical wavelengths.

36. The structure of claim 25, wherein the diamond layer is deposited at less than 600 degrees Celsius.

37. A method for depositing a layer on wafer tooling, comprising:
providing a wafer tool including a substrate having a surface that further includes at least one sidewall; and
depositing a diamond layer having a thickness between 10 nanometers and 1000 nanometers and formed from diamond grains sized to be 50% or less of diamond layer thickness, with the diamond coating being deposited on the surface of the substrate over the at least one sidewall.
